(19) United States
(12) Patent Application Publication
(10) Pub. No.: US 2004/0180483 A1
(43) Pub. Date: Sep. 16, 2004

(54) Method of manufacturing CMOS transistor with LDD structure

(75) Inventors: Jae-eun Park, Yongin-city (KR); Kang-soo Chu, Suwon-city (KR); Joo-won Lee, Suwon-city (KR); Jong-ho Yang, Seoul (KR)

Correspondence Address: Steven M. Mills, MILLS & ONELLO LLP, Suite 605, Eleven Beacon Street, Boston, MA, 02108, US

(73) Assignee: Samsung Electronics Co., Ltd.

(21) Appl. No.: 10/795,705

(22) Filed: Mar. 8, 2004

(30) Foreign Application Priority Data
Mar. 10, 2003 (KR) 03-14779

(51) Int. Cl. H01L 21/336

(52) U.S. Cl. 438/197; 438/199

(57) ABSTRACT

Provided is a method of manufacturing a semiconductor device with an LDD structure using a decreased number of mask-patterning processes using photolithography. The method includes forming an LDD region by implanting low-concentration impurity ions into a semiconductor substrate using a gate electrode, the sidewall of which are exposed, as an ion implantation mask. Then, to form a source/drain region, high-concentration impurity ions are implanted into the semiconductor substrate using a sacrificial masking layer, which covers the top surface and sidewalls of the gate electrode and the top surface of the semiconductor substrate to a uniform thickness, as an ion implantation mask. Implantation of the high-concentration impurity ions may be performed before or after implantation of the low-concentration impurity ions. When a CMOS transistor is formed, additional masks to be used as ion implantation masks are not required for implanting high-concentration impurity ions to form source/drain regions. Thus, the number of times mask-patterning processes are performed is reduced so as to reduce costs.

### BACKGROUND OF THE INVENTION

This application claims priority to Korean Patent Application No. 2003-14779, filed on Mar. 10, 2003, in the Korean Intellectual Property Office, the contents of which are incorporated herein by reference in their entirety.

1. Field of the Invention

The present invention relates to a method of manufacturing a semiconductor device, and more particularly, to a method of manufacturing a semiconductor device with a lightly doped drain (LDD) structure.

2. Description of the Related Art

As there is an increase in the integration density of semiconductor devices, techniques of employing complementary metal oxide semiconductor (CMOS) transistors are being used more widely to integrate an NMOS transistor and a PMOS transistor in a single chip. With finer semiconductor devices, an avalanche effect due to a hot electron effect occurs in a channel region of a CMOS transistor. To prevent this problem, an LDD structure is adopted to improve the performance of a transistor.

In a conventional method of manufacturing a semiconductor device with an LDD structure, after a gate electrode is formed on a semiconductor substrate, a mask-patterning process using photolithography is performed four times. That is, a first mask is patterned to form an LDD region of an n-channel transistor, a second mask is patterned to form an LDD region of a p-channel transistor, a third mask is patterned to form a source/drain region of the n-channel transistor, and a fourth mask is patterned to form a source/drain region of the p-channel transistor. As a result, the unit cost of production increases.

### SUMMARY OF THE INVENTION

The present invention provides a method of manufacturing a semiconductor device, which enables the formation of a CMOS transistor with an LDD structure using a decreased number of mask-patterning processes using photolithography, so as to reduce costs.

In accordance with an aspect of the present invention, there is provided a method of manufacturing a semiconductor device, which comprises forming a gate insulating layer and a gate electrode respectively on a first conductive transistor region and a second conductive transistor region of a semiconductor substrate. Next, a first photoresist pattern is formed to expose only the first conductive transistor region. To form an LDD region in the first conductive transistor region, low-concentration first-conductivity-type impurity ions are implanted into the semiconductor substrate using the gate electrode and the first photoresist pattern as an ion implantation mask. A first sacrificial masking layer is formed to cover the sidewalls of the gate electrode formed in the first conductive transistor region. To form a source/drain region in the first conductive transistor region, high-concentration first-conductivity-type impurity ions are implanted into the semiconductor substrate using the gate electrode, the first photoresist pattern, and the first sacrificial masking layer as an ion implantation mask. Then, the first sacrificial masking layer and the first photoresist pattern are removed. Thereafter, insulating spacers are formed on the sidewalls of the gate insulating layer and the gate electrode.

The first sacrificial masking layer may be a blanket masking layer that covers exposed surfaces of the semiconductor substrate, the gate electrode, and the first photoresist pattern to a uniform thickness. Alternatively, the first sacrificial masking layer may be a plurality of masking spacers that cover the sidewalls of the gate electrode so as to partially expose the surface of the semiconductor substrate. The blanket masking layer can be formed using atomic layer deposition (ALD) at a temperature of 200° C. or less. The masking spacers are formed by etching the blanket masking layer using an etchback process.

Preferably, the first sacrificial masking layer is formed to cover the sidewalls of the gate electrode to a first width, and the insulating spacers are formed to cover the sidewalls of the gate electrode to a second width, which is less than the first width.

In one embodiment, the blanket masking layer is formed of at least one of SiO₂ and Si₃N₄. In one embodiment, forming the first sacrificial masking layer comprises forming a SiO₂ layer by atomic layer deposition using Si₂Cl₆, H₂O, and pyridine.

In one embodiment, after implanting the low-concentration first-conductivity-type impurity ions, a halo implantation region is formed by implanting second-conductivity-type impurity ions into the first conductive transistor region to heighten the impurity concentration of the active region adjacent to the LDD region.

The insulating spacers can be formed in the first conductive transistor region and the second conductive transistor region at the same time.

In one embodiment, before the insulating spacers are formed, a source/drain region is formed in the second conductive transistor region. To form the source/drain region, a second photoresist pattern is formed to expose only the second conductive transistor region. A lightly doped drain region is formed in the second conductive transistor region by implanting low-concentration second-conductivity-type impurity ions using the gate electrode and the second photoresist pattern as an ion implantation mask. A second sacrificial masking layer is formed to cover the sidewalls of the gate electrode formed in the second conductive transistor region. A source/drain region is formed in the second conductive transistor region by implanting high-concentration second-conductivity-type impurity ions into the semiconductor substrate using the gate electrode, the second photoresist pattern, and the second sacrificial masking layer as an ion implantation mask. The second sacrificial masking layer and the second photoresist pattern are removed.

The second sacrificial masking layer can be a blanket masking layer that covers exposed surfaces of the semiconductor substrate, the gate electrode, and the second photoresist pattern to a uniform thickness. Implanting the high-concentration second-conductivity-type impurity ions can use the second sacrificial masking layer, which is the blanket masking layer, as an ion implantation mask.

The second sacrificial masking layer can be a plurality of masking spacers that cover the sidewalls of the gate electrode so as to partially expose the surface of the semiconductor substrate. Implanting the high-concentration second-conductivity-type impurity ions can use the second sacrificial masking layer, which is a plurality of masking spacers, as an ion implantation mask.

Forming the second sacrificial masking layer can include forming a blanket masking layer using atomic layer deposition at a temperature of 200° C. or less.

The blanket masking layer can be formed of at least one of SiO₂ and Si₃N₄.

Forming the second sacrificial masking layer can include forming a SiO₂ layer by atomic layer deposition using Si₂Cl₆, H₂O, and pyridine.

Forming the second sacrificial masking layer can further include forming masking spacers to cover the sidewalls of the gate electrode and the sidewalls of the second photoresist pattern by etching back the blanket masking layer.

The second sacrificial masking layer can be formed to cover the sidewalls of the gate electrode to a first width, and the insulating spacers can be formed to cover the sidewalls of the gate electrode to a second width that is less than the first width.

In one embodiment, after implanting the low-concentration second-conductivity-type impurity ions, a halo implantation region is formed by implanting first-conductivity-type impurity ions into the second conductive transistor region to heighten the impurity concentration of the active region adjacent to the lightly doped drain region.

In accordance with another aspect of the present invention, there is provided a method of manufacturing a semiconductor device, which comprises forming a gate insulating layer and a gate electrode on a semiconductor substrate having a first conductive transistor region and a second conductive transistor region. A photoresist pattern is formed to expose only the first conductive transistor region. A sacrificial masking layer is formed to cover the sidewalls of the gate electrode. High-concentration first-conductivity-type impurity ions are implanted into the semiconductor substrate using the gate electrode, the photoresist pattern, and the sacrificial masking layer as an ion implantation mask, thereby forming a source/drain region. The sacrificial masking layer is removed so as to expose the sidewalls of the gate electrode. Low-concentration first-conductivity-type impurity ions are implanted into the semiconductor substrate, where the source/drain region is formed, using the gate electrode and the photoresist pattern as an ion implantation mask, thereby forming an LDD region. Next, the photoresist pattern is removed. Then, insulating spacers are formed on the sidewalls of the gate electrode.

The sacrificial masking layer can be a blanket masking layer that covers exposed surfaces of the semiconductor substrate, the gate electrode, and the photoresist pattern to a uniform thickness.

Alternatively, the sacrificial masking layer can be a plurality of masking spacers that cover the sidewalls of the gate electrode so as to expose the top surface of the gate electrode and part of the surface of the semiconductor substrate.

The sacrificial masking layer can be formed using atomic layer deposition at a temperature of 200° C. or less.

The sacrificial masking layer can be formed of at least one of SiO₂ and Si₃N₄. Forming the sacrificial masking layer can include forming a SiO₂ layer by atomic layer deposition using Si₂Cl₆, H₂O, and pyridine.

The sacrificial masking layer can be formed to cover the sidewalls of the gate electrode to a first width, and the insulating spacers can be formed to cover the sidewalls of the gate electrode to a second width that is less than the first width.

In one embodiment, after forming the lightly doped drain region, a halo implantation region is formed by implanting second-conductivity-type impurity ions into the first conductive transistor region to heighten the impurity concentration of the active region adjacent to the lightly doped drain region.

In accordance with yet another aspect of the present invention, there is provided a method of manufacturing a semiconductor device, which comprises forming a gate insulating layer and a gate electrode on a semiconductor substrate. To form an LDD region in the semiconductor substrate, low-concentration impurity ions are implanted into the semiconductor substrate using the gate electrode, the sidewalls of which are exposed, as an ion implantation mask. To form a source/drain region, high-concentration impurity ions are implanted into the semiconductor substrate using a sacrificial masking layer, which covers the top surface and the sidewalls of the gate electrode and the top surface of the semiconductor substrate to a uniform thickness, as an implantation mask.

In one embodiment, the sacrificial masking layer is formed using an insulating layer by ALD.

Implanting the high-concentration impurity ions may be performed before or after implanting the low-concentration impurity ions.

The insulating layer can be formed of at least one of SiO₂ and Si₃N₄.

According to the present invention, when LDD-type source/drain regions are formed in an n-channel transistor region and a p-channel transistor region, the number of times mask-patterning processes using photolithography are performed is reduced to twice. Thus, the unit cost of production can be reduced. Also, a sacrificial masking layer, which is used as a mask when high-concentration impurity ions are implanted for forming a source/drain region, is removed and insulating spacers with a minimum width are formed again on the sidewalls of a gate electrode. Therefore, a sufficient effective channel length for obtaining desired operative characteristics of a cell transistor and sufficient contact areas between source/drain regions and a contact plug can be secured so that reliability and operative characteristics of the cell transistor can be improved.

### BRIEF DESCRIPTION OF THE DRAWINGS

The foregoing and other objects, features and advantages of the invention will be apparent from the more particular description of a preferred embodiment of the invention, as illustrated in the accompanying drawings in which like reference characters refer to the same parts throughout the different views. The drawings are not necessarily to scale, emphasis instead being placed upon illustrating the principles of the invention.

FIGS. 1 through 10 are cross-sectional views illustrating a method of manufacturing a semiconductor device according to a first embodiment of the present invention.

FIGS. 11 and 12 are cross-sectional views illustrating a method of manufacturing a semiconductor device according to a second embodiment of the present invention.

FIGS. 13 through 17 are cross-sectional views illustrating a method of manufacturing a semiconductor device according to a third embodiment of the present invention.

### DETAILED DESCRIPTION OF THE INVENTION

The present invention will now be described more fully with reference to the accompanying drawings, in which preferred embodiments of the invention are shown. This invention may, however, be embodied in different forms and should not be construed as being limited to the embodiments set forth herein. In the drawings, the size or thickness of layers and regions may be exaggerated for clarity.

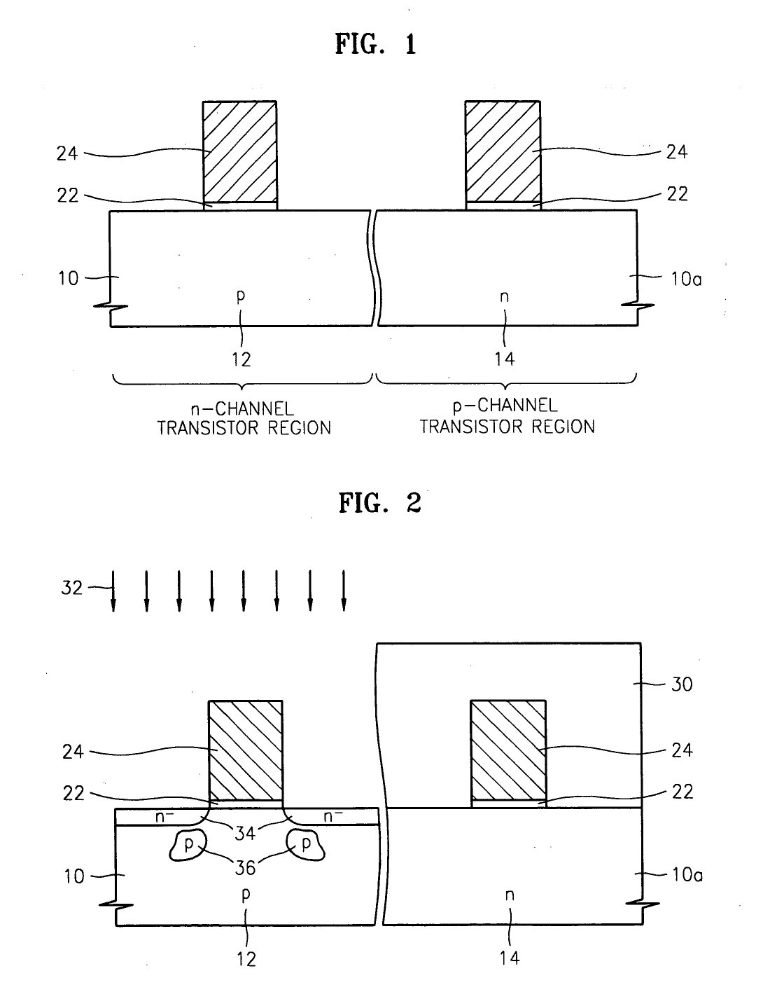

FIGS. 1 through 10 are cross-sectional views illustrating a method of manufacturing a semiconductor device according to a first embodiment of the present invention.

Referring to FIG. 1, an active region is defined using an isolation process in a semiconductor substrate 10 formed of a p-type silicon substrate. Then, an n-type well region 10a is formed in the active region of the semiconductor substrate 10 so as to form an n-channel transistor region 12 and a p-channel transistor region 14. Next, a gate insulating layer 22 and a gate electrode 24 are formed on the surfaces of the semiconductor substrate 10 in the n-channel transistor region 12 and the p-channel transistor region 14.

Referring to FIG. 2, a first photoresist pattern 30 is formed on and around the gate electrode 24 formed in the p-channel transistor region 14 so as to expose only the n-channel transistor region 12. Next, low-concentration n-type impurity ions 32, for example, arsenic ions, are implanted into the semiconductor substrate 10 using the gate electrode 24 formed in the n-channel transistor region 12 and the first photoresist pattern 30 as an ion implantation mask. As a result, an n⁻-type LDD region 34 is formed in the n-channel transistor region 12.

Thereafter, p-type impurity ions are implanted into the n-channel transistor region 12 using the gate electrode 24 formed in the n-channel transistor region 12 as an ion implantation mask, thereby forming a halo implantation region 36 adjacent to the LDD region 34. The ion implantation process for forming the halo implantation region 36 is carried out at a predetermined angle from normal to the semiconductor substrate 10, for example, at an angle of 25° to 50°. The formation of the halo implantation region 36 may be optionally omitted.

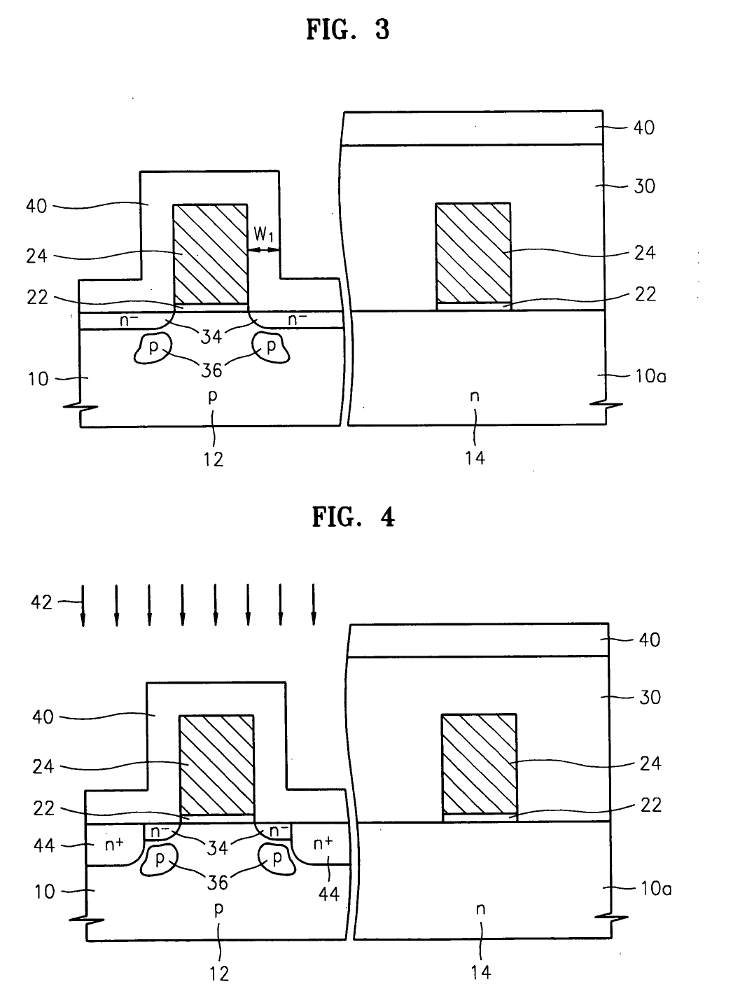

Referring to FIG. 3, a first sacrificial masking layer 40 is formed to a first width of W₁ on the sidewalls of the gate electrode 24 formed in the n-channel transistor region 12. In FIG. 3, the first sacrificial masking layer 40 is formed as a blanket masking layer to cover exposed surfaces of the semiconductor substrate 10, the gate electrode 24, and the first photoresist pattern 30 to a uniform thickness of W₁.

The first sacrificial masking layer 40, a blanket masking layer, requires good step coverage characteristics so that it can be uniformly formed on all of the exposed regions of the semiconductor substrate 10. Also, the first sacrificial masking layer 40 should be formed at a relatively low temperature of 200° C. or less to prevent burning of the first photoresist pattern 30. To satisfy the foregoing conditions, the first sacrificial masking layer 40 is preferably formed using atomic layer deposition (ALD) at a temperature of 200° C. or less. The first sacrificial masking layer 40 may be formed of SiO₂ or Si₃N₄ but preferably formed of SiO₂. Since the SiO₂ layer formed using ALD can also be deposited on the photoresist pattern 30, the first sacrificial masking layer 40 formed of SiO₂ can be uniformly formed on all of the exposed regions of the semiconductor substrate 10. When the first sacrificial masking layer 40 is formed of SiO₂, an ALD process is performed using, for example, Si₂Cl₆, H₂O, and pyridine.

Referring to FIG. 4, high-concentration n-type impurity ions 42 are implanted into the semiconductor substrate 10 using the gate electrode 24, the first photoresist pattern 30, and the first sacrificial masking layer 40 as an ion implantation mask. Here, ion implantation energy should be adjusted in consideration of the thickness of the first sacrificial masking layer 40 formed on the semiconductor substrate 10 such that a proper range of projection (Rp) or ΔRp is obtained. As a result, an n⁺-type source/drain region 44 is formed in the n-channel transistor region 12.

Referring to FIG. 5, the first sacrificial masking layer 40 and the first photoresist pattern 30 are removed until the top surface of the semiconductor substrate 10 adjacent to the gate electrode 24 is exposed. While the first sacrificial masking layer 40 may be removed using a wet etchant, such as diluted HF (DHF), the first photoresist pattern 30 may be removed using ashing.

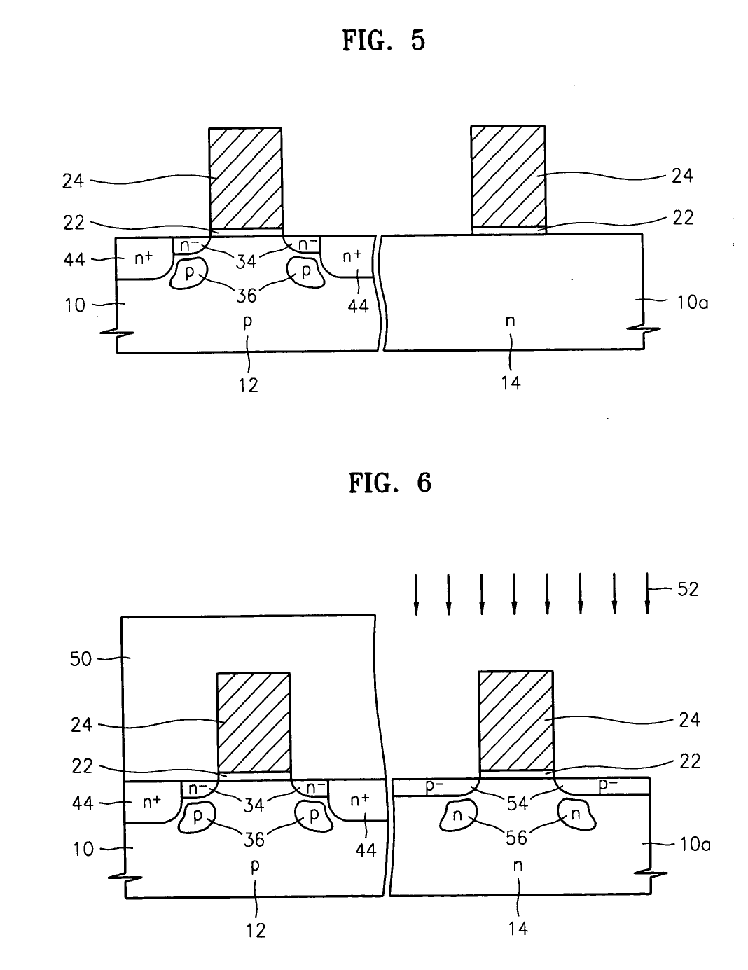

Referring to FIG. 6, a second photoresist pattern 50 is formed on the gate electrode 24 formed in the n-channel transistor region 12 so as to expose only the p-channel transistor region 14. Next, low-concentration p-type impurity ions 52, for example, boron ions, are implanted into the semiconductor substrate 10 using the gate electrode 24 formed in the p-channel transistor region 14 and the second photoresist pattern 50 as an ion implantation mask. As a result, a p⁻-type LDD region 54 is formed in the p-channel transistor region 14.

Thereafter, n-type impurity ions are implanted into the p-channel transistor region 14 using the gate electrode 24 formed in the p-channel transistor region 14 as an ion implantation mask, thereby forming a halo implantation region 56 adjacent to the LDD region 54. The ion implantation process for forming the halo implantation region 56 may be carried out in the same manner as the formation of the halo implantation region 36 as described with reference to FIG. 2. Also, the formation of the halo implantation region 36 may be optionally omitted.

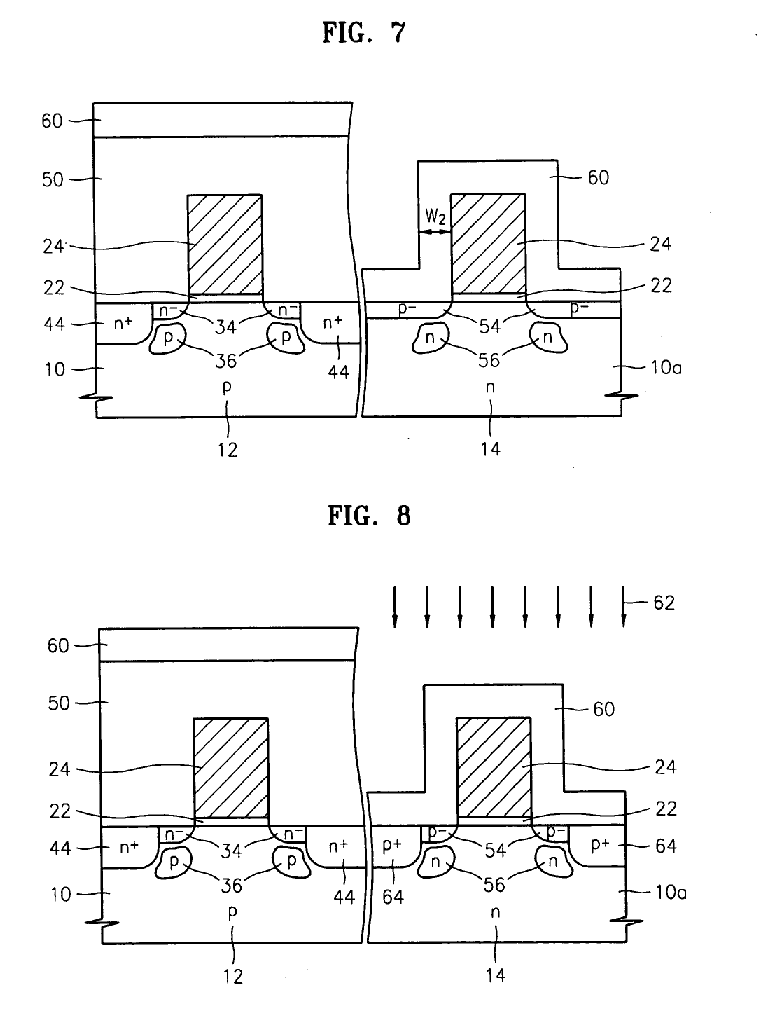

Referring to FIG. 7, a second sacrificial masking layer 60 is formed to a second width of W₂ on the sidewalls of the gate electrode 24 formed in the p-channel transistor region 14. In FIG. 7, the second sacrificial masking layer 60 is formed as a blanket masking layer to cover exposed surfaces of the semiconductor substrate 10, the gate electrode 24, and the second photoresist pattern 50 to a uniform thickness of W₂. The second sacrificial masking layer 60 may be formed in the same manner as the formation of the first sacrificial masking layer 40 as described with reference to FIG. 3.

Referring to FIG. 8, high-concentration p-type impurity ions 62 are implanted into the semiconductor substrate 10 using the gate electrode 24, the second photoresist pattern 50, and the second sacrificial masking layer 60 as an ion implantation mask. Here, ion implantation energy should be adjusted in consideration of the thickness of the second sacrificial masking layer 60 formed on the semiconductor substrate 10. As a result, a p⁺-type source/drain region 64 is formed in the p-channel transistor region 14.

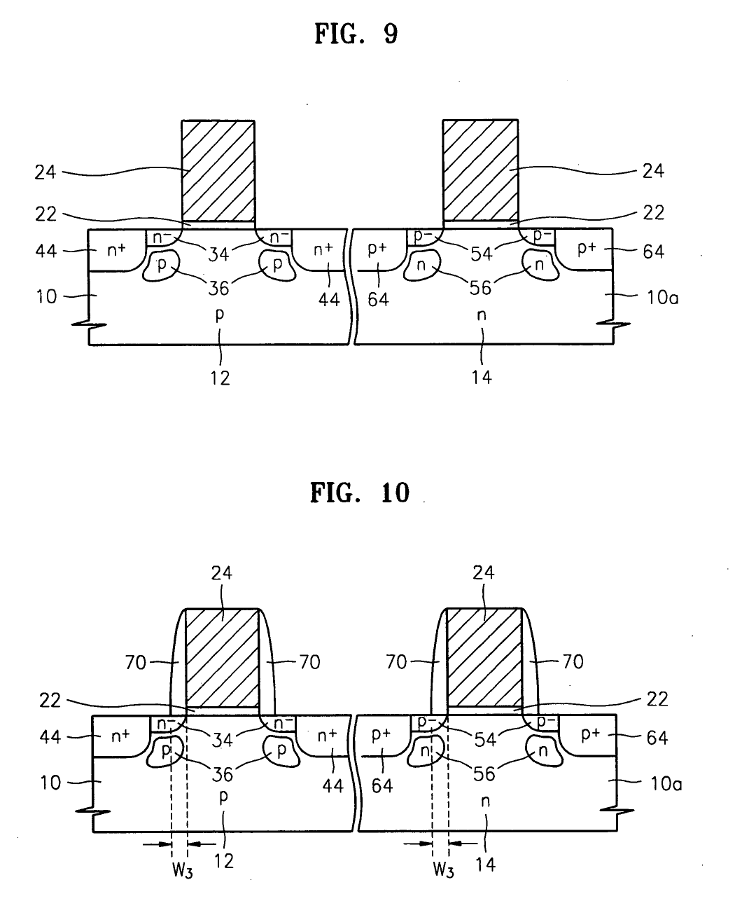

Referring to FIG. 9, the second sacrificial masking layer 60 and the second photoresist pattern 50 are removed in the same manner as described with reference to FIG. 5 until the top surface of the semiconductor substrate 10 adjacent to the gate electrode 24 is exposed.

Referring to FIG. 10, an insulating layer (e.g., a silicon oxide layer) is deposited on the entire surface of the resultant structure of FIG. 9 to a predetermined thickness and then etched using an etchback process. Thus, insulating spacers 70 are formed on the sidewalls of the gate insulating layer 22 and the gate electrode 24. The insulating spacers 70 cover the sidewalls of the gate electrode 24 to a third width of W₃.

Here, the third width W₃ of the insulating spacers 70 formed on the sidewalls of the gate electrode 24 is less than the first width W₁ of the first sacrificial masking layer 40 and less than the second width W₂ of the second sacrificial masking layer 60. Thus, sufficient contact areas between a contact plug and the source/drain region 44 and 64 can be secured in the n-channel transistor region 12 and the p-channel transistor region 14. As a result, contact resistances therebetween can be reduced.

According to the first embodiment as described above, to form a CMOS transistor with an LDD structure, high-concentration impurity ions are implanted using the first sacrificial masking layer 40 and the second sacrificial masking layer 60 as ion implantation masks in the n-channel transistor region 12 and the p-channel transistor region 14, respectively. Therefore, when LDD-type source/drain regions are formed in the n-channel transistor region and the p-channel transistor region, the number of times mask-patterning processes using photolithography are performed can be reduced to twice.

Also, when the first sacrificial masking layer 40 and the second sacrificial masking layer 60 are formed, their thicknesses, i.e., the first width W₁ and the second width W₂, can be adjusted to secure a sufficient effective channel length so as to obtain desired operative characteristics of a cell transistor, without consideration of contact areas between source/drain regions and a contact plug formed thereon. Also, the first sacrificial masking layer 40 and the second sacrificial masking layer 60 can be formed in the shape of blanket masking layers, which cover all of the exposed regions of the semiconductor substrate 10, using simple processes. Further, the first sacrificial masking layer 40 and the second sacrificial masking layer 60 can function as protection layers in the high-concentration ion implantation processes, thereby preventing other layers from being damaged.

In addition, after the source/drain regions 44 and 64 are formed in the n-channel transistor region 12 and the p-channel transistor region 14, respectively, when the insulating spacers 70 are formed on the sidewalls of the gate electrode 24, the width W₃ of the insulating spacers 70 can be adjusted to secure sufficient contact areas between the source/drain regions 44 and 64 and a contact plug, without consideration of an effective channel length of a cell transistor. Thus, an effective channel length and the contact areas can be separately adjusted so as to obtain desired operative characteristics of a cell transistor of a highly integrated device so that the reliability of the cell transistor can be improved.

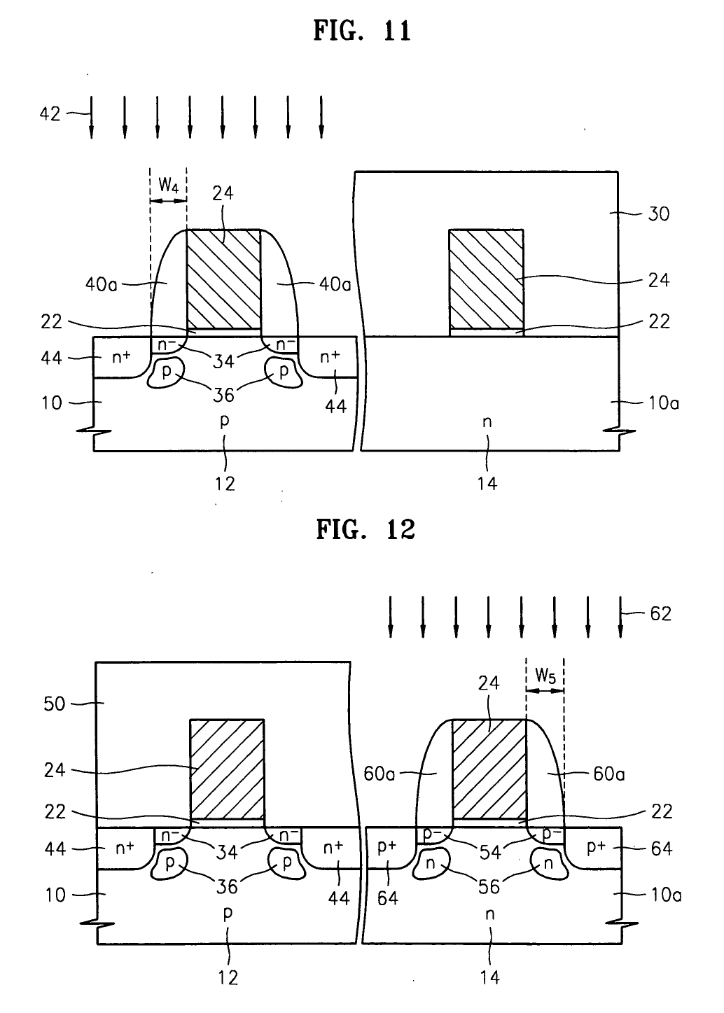

FIGS. 11 through 12 are cross-sectional views illustrating a method of manufacturing a semiconductor device according to a second embodiment of the present invention.

The second embodiment is generally similar to the first embodiment, except that, in the second embodiment, first masking spacers 40a and second masking spacers 60a, which cover the sidewalls of a gate electrode 24, are used as ion implantation masks during implantation processes of high-concentration impurity ions 42 and 62, respectively. In FIGS. 11 and 12, the same reference numerals in the first and second embodiments represent the same elements.

More specifically, in the second embodiment, initially, a first sacrificial masking layer 40 is formed as a blanket masking layer on a semiconductor substrate 10 as described with reference to FIGS. 1 through 3. Thereafter, the first sacrificial masking layer 40 is etched using an etchback process. Thus, as shown in FIG. 11, the first masking spacers 40a are formed in an n-channel transistor region 12 so as to cover the sidewalls of the gate electrode 24 to a fourth width W₄ and partially expose the surface of the semiconductor substrate 10. The fourth width W₄ of the first masking spacers 40a can be designed to secure a sufficient effective channel length in the n-channel transistor region 12.

Next, high-concentration n-type impurity ions 42 are implanted into the semiconductor substrate 10 using the first masking spacers 40a as an ion implantation mask. As a result, an n⁺-type source/drain region 44 is formed in the n-channel transistor region 12.

Thereafter, a second sacrificial masking layer 60 is formed as a blanket masking layer on the semiconductor substrate 10 as described with reference to FIGS. 5 through 7. Then, the second sacrificial masking layer 60 is etched using an etchback process. Thus, as shown in FIG. 12, second masking spacers 60a are formed in a p-channel transistor region 14 so as to cover the sidewalls of the gate electrode 24 to a fifth width W₅ and partially expose the surface of the semiconductor substrate 10. The fifth width W₅ of the second masking spacers 60a can be designed to secure a sufficient effective channel length in the p-channel transistor region 14.

Next, high-concentration p-type impurity ions 62 are implanted into the semiconductor substrate 10 using the second masking spacers 60a as an ion implantation mask. As a result, a p⁺-type source/drain region 64 is formed in the p-channel transistor region 14.

Thereafter, a subsequent process is carried out in the same manner as described with reference to FIGS. 9 and 10. Thus, insulating spacers 70 are formed on the sidewalls of the gate insulating layer 22 and the gate electrode 24.

Here, the third width W₃ of the insulating spacers 70 is less than the fourth width W₄ of the first masking spacers 40a and less than the fifth width W₅ of the second masking spacers 60a. Therefore, sufficient contact areas between a contact plug and the source/drain regions 44 and 64 can be secured in the n-channel transistor region 12 and the p-channel transistor region 14, thereby reducing contact resistance therebetween.

In the second embodiment, in a state where the top surface of the semiconductor substrate 10 is exposed, high-concentration n-type impurity ions 42 and high-concentration p-type impurity ions 62 are implanted using the first masking spacers 40a and the second masking spacers 60a as ion implantation masks, respectively. Thus, in comparison to the first embodiment wherein the first and second sacrificial masking layers 40 and 60, as blanket masking layers, function as ion implantation masks, it is easier to adjust ion implantation energy so as to obtain an appropriate Rp.

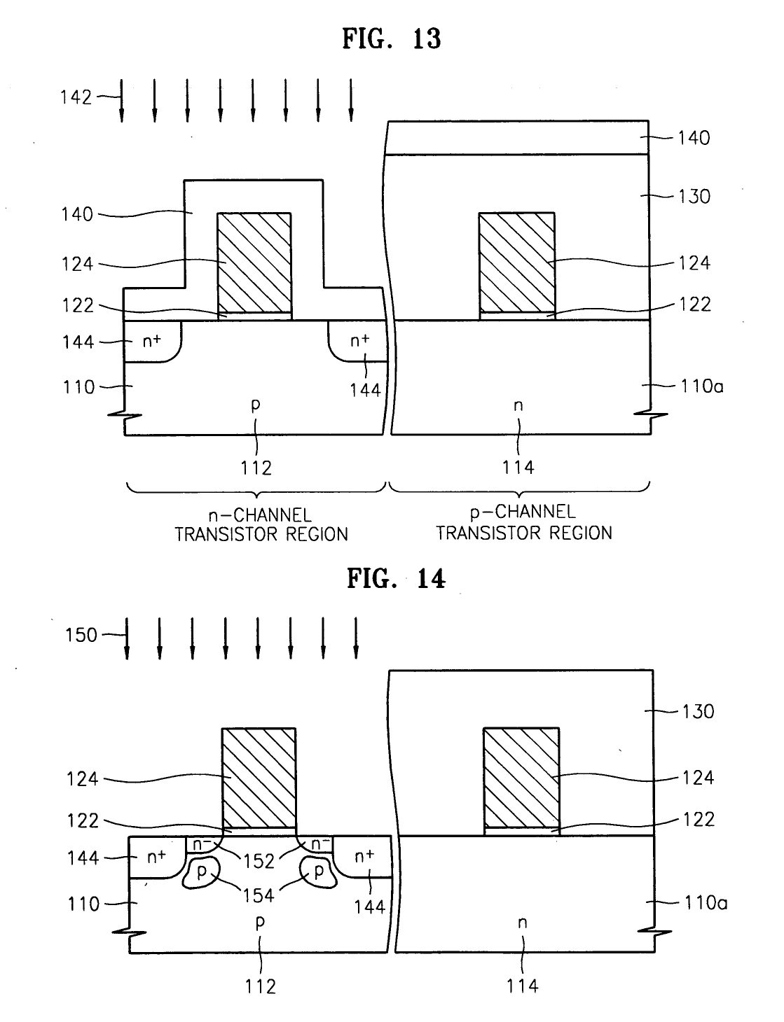

FIGS. 13 through 17 are cross-sectional views illustrating a method of manufacturing a semiconductor device according to a third embodiment of the present invention.

The third embodiment is generally similar to the first embodiment, except that, in the third embodiment, after source/drain regions 144 and 174 are formed by implanting high-concentration impurity ions 142 and 172 using a first sacrificial masking layer 140 and a second sacrificial masking layer 170 as ion implantation masks, respectively, the first sacrificial masking layer 140 and the second sacrificial masking layer 170 are removed, and then LDD regions 152 and 182 are respectively formed in an n-channel transistor region 112 and a p-channel transistor region 114 by implanting low-concentration impurity ions 150 and 180, respectively. The third embodiment will be described in more detail hereinafter.

Referring to FIG. 13, an n-type well region 110a is formed in an active region of a semiconductor substrate 110 as described with reference to FIG. 1, so as to form the n-channel transistor region 112 and the p-channel transistor region 114. Next, a gate insulating layer 122 and a gate electrode 124 are formed in the n-channel transistor region 112 and the p-channel transistor region 114.

Thereafter, a first photoresist pattern 130 is formed on the gate electrode 124 formed in the p-channel transistor 114 so as to expose only the n-channel transistor region 112. Next, a first sacrificial masking layer 140 is formed to cover the sidewalls of the gate electrode 124 formed in the n-channel transistor region 1 12 in the same manner as the formation of the first sacrificial masking layer 40 of FIG. 3. In FIG. 13, the first sacrificial masking layer 140 is formed as a blanket masking layer that covers exposed surfaces of the semiconductor substrate 110, the gate electrode 124, and the first photoresist pattern 130 to a uniform thickness. However, as shown in FIG. 11, the first sacrificial masking layer 140 may be formed as masking spacers covering the sidewalls of the gate electrode 124 instead.

High-concentration n-type impurity ions 142 are implanted into the semiconductor substrate 110 using the gate electrode 124, the first photoresist pattern 130, and the first sacrificial masking layer 140 as an ion implantation mask, thereby forming an n⁺-type source/drain region 144 in the n-channel transistor region 112.

Referring to FIG. 14, the first sacrificial masking layer 140 is removed so as to expose the sidewalls of the gate electrode 124 formed in the n-channel transistor region 112 and the top surface of the semiconductor substrate 110 adjacent to the sidewalls of the gate electrode 124. Thereafter, low-concentration n-type impurity ions 150 are implanted into the semiconductor substrate 110 using the gate electrode 124 formed in the n-channel transistor region 112 and the first photoresist pattern 130 as an ion implantation mask, thereby forming an n⁻-type LDD region 152 in the n-channel transistor region 112.

Next, a halo implantation region 154 is formed in the n-channel transistor region 112 in the same manner as described with reference to FIG. 2.

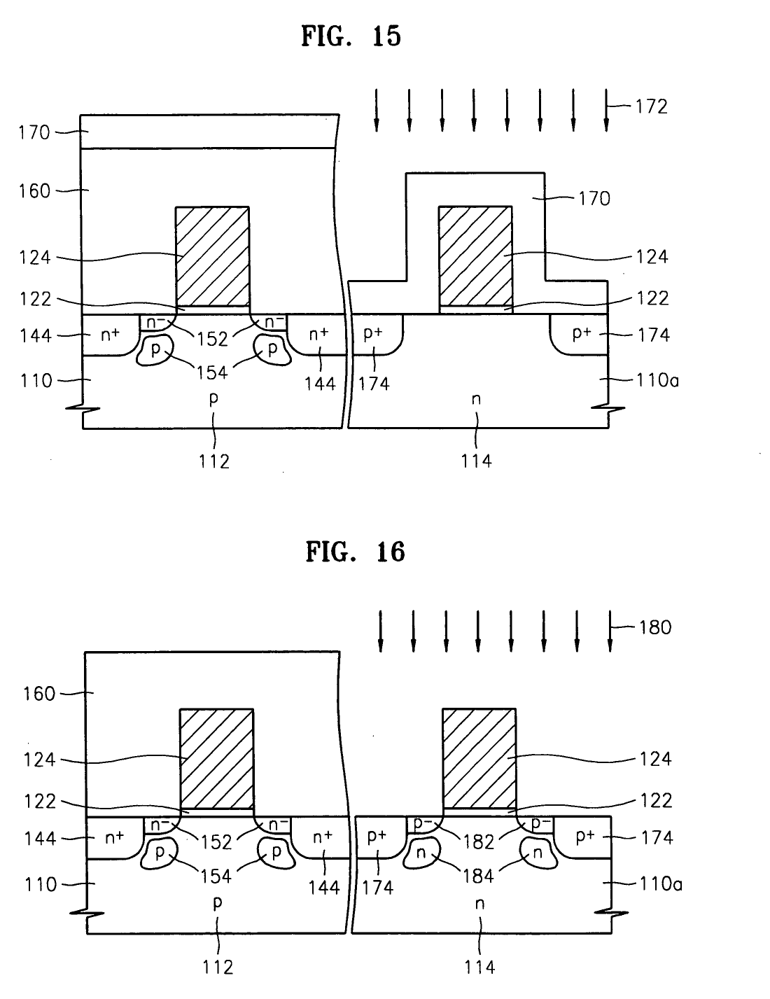

Thereafter, the first photoresist pattern 130 is removed, and as shown in FIG. 15, a second photoresist pattern 160 is formed on the semiconductor substrate 110 to expose only the p-channel transistor region 114. Next, a second sacrificial masking layer 170 is formed to cover the sidewalls of the gate electrode 124 formed in the p-channel transistor region 114 in the same manner as the formation of the second sacrificial masking layer 60 of FIG. 7. In FIG. 15, the second sacrificial masking layer 170 is formed as a blanket masking layer that covers exposed surfaces of the semiconductor substrate 110, the gate electrode 124, and the second photoresist pattern 160 to a uniform thickness. However, as shown in FIG. 12, the second sacrificial masking layer 170 may be formed as masking spacers covering the sidewalls of the gate electrode 124 instead.

High-concentration p-type impurity ions 172 are implanted into the semiconductor substrate 110 using the gate electrode 124, the second photoresist pattern 160, and the second sacrificial masking layer 170 as an ion implantation mask, thereby forming a p⁺-type source/drain region 174 in the p-channel transistor region 114.

Thereafter, the second sacrificial masking layer 170 is removed so as to expose the sidewalls of the gate electrode 124 formed in the p-channel transistor region 114 and the top surface of the semiconductor substrate 110 adjacent to the sidewalls of the gate electrode 124. Next, as shown in FIG. 16, low-concentration p-type impurity ions 180 are implanted into the semiconductor substrate 110 using the gate electrode 124 formed in the p-channel transistor region 114 and the second photoresist pattern 160 as an ion implantation mask, thereby forming a p⁻-type LDD region 182 in the p-channel transistor region 114.

Next, a halo implantation 184 is formed in the p-channel transistor region 114 in the same manner as described with reference to FIG. 6.

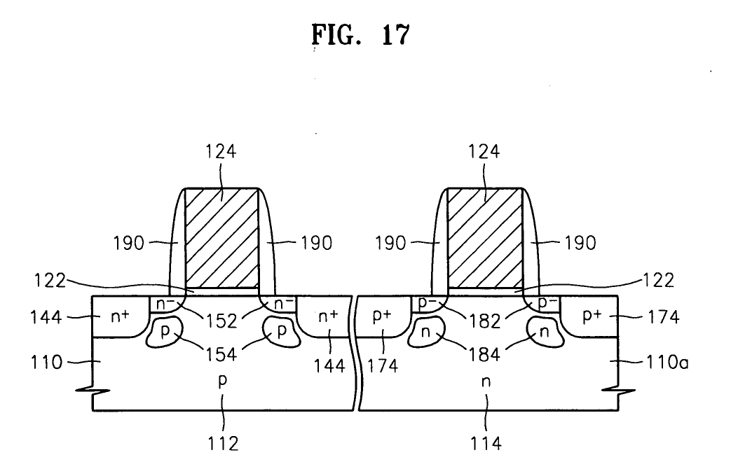

Referring to FIG. 17, the second photoresist pattern 160 is removed, and insulating spacers 190 are formed on the sidewalls of the gate insulating layer 122 and the gate electrode 124 in the same manner as described with reference to FIG. 10.

In the drawings and specification, there have been disclosed typical preferred embodiments of the invention and, although, specific terms have been employed, they have been used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims. For example, although the formation of the n-channel transistor region is followed by the formation of the p-channel transistor region in the present embodiments, it is also possible that the formation of the p-channel transistor region is followed by the formation of the n-channel transistor region. Also, although a method of manufacturing a CMOS transistor is described in the present invention, the method of the present invention can be applied to a single-channel-type transistor, such as an NMOS transistor or a PMOS transistor.

According to the present invention, before or after LDD regions are formed in an n-channel transistor region and a p-channel transistor region, source/drain regions are formed by implanting high-concentration impurity ions using sacrificial masking layers, which cover the sidewalls of a gate electrode, as an ion implantation mask, and then, the sacrificial masking layers are removed. Accordingly, when LDD-type source/drain regions are formed in the n-channel transistor region and the p-channel transistor region, the number of times mask-patterning processes using photolithography are performed can be reduced to twice, and the unit cost of production can be lowered as compared to conventional methods.

Also, when sacrificial masking layers are formed, their thickness can be adjusted so as to secure a sufficient effective channel length to obtain desired operative characteristics of a cell transistor, without consideration of contact areas between source/drain regions and a contact plug formed thereon.

Further, after the LDD-type source/drain regions are formed in the n-channel transistor region and the p-channel transistor region, insulating spacers can be formed to have a minimum thickness sufficient enough to insulate the gate electrode. Thus, sufficient contact areas can be secured between the source/drain regions and the contact plug so that the reliability and operative characteristics of the cell transistor can be improved.

While the present invention has been particularly shown and described with reference to preferred embodiments thereof, it will be understood by those of ordinary skill in the art that various changes in form and details may be made therein without departing from the spirit and scope of the present invention as defined by the following claims.

What is claimed is:

1. A method of manufacturing a semiconductor device, the method comprising:
forming a gate insulating layer and a gate electrode on a first conductive transistor region and a second conductive transistor region of a semiconductor substrate;
forming a first photoresist pattern to expose only the first conductive transistor region;
forming a lightly doped drain region in the first conductive transistor region by implanting low-concentration first-conductivity-type impurity ions into the semiconductor substrate using the gate electrode and the first photoresist pattern as an ion implantation mask;
forming a first sacrificial masking layer to cover the sidewalls of the gate electrode that is formed in the first conductive transistor region;
forming a source/drain region in the first conductive transistor region by implanting high-concentration first-conductivity-type impurity ions into the semiconductor substrate using the gate electrode, the first photoresist pattern, and the first sacrificial masking layer as an ion implantation mask;
removing the first sacrificial masking layer and the first photoresist pattern; and
forming insulating spacers on the sidewalls of the gate insulating layer and the gate electrode.

2. The method of claim 1, wherein the first sacrificial masking layer is a blanket masking layer that covers the exposed surfaces of the semiconductor substrate, the gate electrode, and the first photoresist pattern to a uniform thickness,
and wherein implanting high-concentration first-conductivity-type impurity ions uses the first sacrificial masking layer, which is the blanket masking layer, as an ion implantation mask.

3. The method of claim 1, wherein the first sacrificial masking layer is a plurality of masking spacers that cover the sidewalls of the gate electrode so as to partially expose the surface of the semiconductor substrate,
and wherein implanting high-concentration first-conductivity-type impurity ions uses the first sacrificial masking layer, which is a plurality of masking spacers, as an ion implantation mask.

4. The method of claim 1, wherein forming the first sacrificial masking layer comprises forming a blanket masking layer using atomic layer deposition at a temperature of 200° C. or less.

5. The method of claim 4, wherein the blanket masking layer is formed of at least one of SiO₂ and Si₃N₄.

6. The method of claim 4, wherein forming the first sacrificial masking layer comprises forming a SiO₂ layer by atomic layer deposition using Si₂Cl₆, H₂O, and pyridine.

7. The method of claim 4, wherein forming the first sacrificial masking layer further comprises forming masking spacers to cover the sidewalls of the gate electrode and the sidewalls of the first photoresist pattern by etching back the blanket masking layer.

8. The method of claim 1, wherein the first sacrificial masking layer is formed to cover the sidewalls of the gate electrode to a first width, and the insulating spacers are formed to cover the sidewalls of the gate electrode to a second width that is less than the first width.

9. The method of claim 1, after implanting the low-concentration first-conductivity-type impurity ions, further comprising forming a halo implantation region by implanting second-conductivity-type impurity ions into the first conductive transistor region to heighten the impurity concentration of the active region adjacent to the LDD region.

10. The method of claim 1, wherein the insulating spacers are formed in the first conductive transistor region and the second conductive transistor region at the same time.

11. The method of claim 1, before forming the insulating spacers, further comprising forming a source/drain region in the second conductive transistor region,
wherein forming the source/drain region includes:
forming a second photoresist pattern to expose only the second conductive transistor region;
forming a lightly doped drain region in the second conductive transistor region by implanting low-concentration second-conductivity-type impurity ions using the gate electrode and the second photoresist pattern as an ion implantation mask;
forming a second sacrificial masking layer to cover the sidewalls of the gate electrode formed in the second conductive transistor region;
forming a source/drain region in the second conductive transistor-region by implanting high-concentration second-conductivity-type impurity ions into the semiconductor substrate using the gate electrode, the second photoresist pattern, and the second sacrificial masking layer as an ion implantation mask; and
removing the second sacrificial masking layer and the second photoresist pattern.

12. The method of claim 11, wherein the second sacrificial masking layer is a blanket masking layer that covers exposed surfaces of the semiconductor substrate, the gate electrode, and the second photoresist pattern to a uniform thickness,
and wherein implanting the high-concentration second-conductivity-type impurity ions uses the second sacrificial masking layer, which is the blanket masking layer, as an ion implantation mask.

13. The method of claim 11, wherein the second sacrificial masking layer is a plurality of masking spacers that cover the sidewalls of the gate electrode so as to partially expose the surface of the semiconductor substrate,
and wherein implanting the high-concentration second-conductivity-type impurity ions uses the second sacrificial masking layer, which is a plurality of masking spacers, as an ion implantation mask.

14. The method of claim 11, wherein forming the second sacrificial masking layer comprises forming a blanket masking layer using atomic layer deposition at a temperature of 200° C. or less.

15. The method of claim 14, wherein the blanket masking layer is formed of at least one of SiO₂ and Si₃N₄.

16. The method of claim 14, wherein forming the second sacrificial masking layer comprises forming a SiO₂ layer by atomic layer deposition using Si₂Cl₆, H₂O, and pyridine.

17. The method of claim 14, wherein forming the second sacrificial masking layer further comprises forming masking spacers to cover the sidewalls of the gate electrode and the sidewalls of the second photoresist pattern by etching back the blanket masking layer.

18. The method of claim 11, wherein the second sacrificial masking layer is formed to cover the sidewalls of the gate electrode to a first width, and the insulating spacers are formed to cover the sidewalls of the gate electrode to a second width that is less than the first width.

19. The method of claim 11, after implanting the low-concentration second-conductivity-type impurity ions, further comprising forming a halo implantation region by implanting first-conductivity-type impurity ions into the second conductive transistor region to heighten the impurity concentration of the active region adjacent to the lightly doped drain region.

20. A method of manufacturing a semiconductor device, the method comprising:
forming a gate insulating layer and a gate electrode on a semiconductor substrate having a first conductive transistor region and a second conductive transistor region;
forming a photoresist pattern to expose only the first conductive transistor region;
forming a sacrificial masking layer to cover the sidewalls of the gate electrode;
forming a source/drain region by implanting high-concentration first-conductivity-type impurity ions into the semiconductor substrate using the gate electrode, the photoresist pattern, and the sacrificial masking layer as an ion implantation mask;
removing the sacrificial masking layer to expose the sidewalls of the gate electrode;
forming a lightly doped drain region by implanting low-concentration first-conductivity-type impurity ions into the semiconductor substrate, where the source/drain region is formed, using the gate electrode and the photoresist pattern as an ion implantation mask;
removing the photoresist pattern; and
forming insulating spacers on the sidewalls of the gate electrode.

21. The method of claim 20, wherein the sacrificial masking layer is a blanket masking layer that covers exposed surfaces of the semiconductor substrate, the gate electrode, and the photoresist pattern to a uniform thickness.

22. The method of claim 20, wherein the sacrificial masking layer is a plurality of masking spacers that cover the sidewalls of the gate electrode so as to expose the top surface of the gate electrode and part of the surface of the semiconductor substrate.

23. The method of claim 20, wherein the sacrificial masking layer is formed using atomic layer deposition at a temperature of 200° C. or less.

24. The method of claim 23, wherein the sacrificial masking layer is formed of at least one of SiO₂ and Si₃N₄.

25. The method of claim 23, wherein forming the sacrificial masking layer comprises forming a SiO₂ layer by atomic layer deposition using Si₂Cl₆, H₂O, and pyridine.

26. The method of claim 20, wherein the sacrificial masking layer is formed to cover the sidewalls of the gate electrode to a first width, and the insulating spacers are formed to cover the sidewalls of the gate electrode to a second width that is less than the first width.

27. The method of claim 20, after forming the lightly doped drain region, further comprising forming a halo implantation region by implanting second-conductivity-type impurity ions into the first conductive transistor region to heighten the impurity concentration of the active region adjacent to the lightly doped drain region.

28. A method of manufacturing a semiconductor device, the method comprising:
forming a gate insulating layer and a gate electrode on a semiconductor substrate;
forming a lightly doped drain region in the semiconductor substrate by implanting low-concentration impurity ions into the semiconductor substrate using the gate electrode, the sidewalls of which are exposed, as an ion implantation mask; and
forming a source/drain region by implanting high-concentration impurity ions into the semiconductor substrate using a sacrificial masking layer, which covers the top surface and the sidewalls of the gate electrode and the top surface of the semiconductor substrate to a uniform thickness, as an implantation mask.

29. The method of claim 28, wherein the sacrificial masking layer is an insulating layer formed using atomic layer deposition.

30. The method of claim 29, wherein the insulating layer is formed of at least one of SiO₂ and Si₃N₄.

31. The method of claim 28, wherein implanting the high-concentration impurity ions is performed before implanting the low-concentration impurity ions.

32. The method of claim 28, wherein implanting the high-concentration impurity ions is performed after implanting the low-concentration impurity ions.
